(19) United States
(12) Patent Application Publication
(10) Pub. No.: US 2025/0130295 A1
(43) Pub. Date: Apr. 24, 2025

(54) APPARATUS AND METHOD FOR SUPPRESSING INTERFERENCE FIELD IN MAGNETIC SENSORS

(71) Applicant: TDK - Micronas GmbH, Freiburg (DE)

(72) Inventors: David Muthers, Freiburg (DE); Jörg Franke, Freiburg (DE)

(21) Appl. No.: 18/921,331

(22) Filed: Oct. 21, 2024

(30) Foreign Application Priority Data
Oct. 20, 2023 (DE) 10 2023 128 940.3

(51) Int. Cl. G01R 33/025; G01R 33/00

(52) U.S. Cl. CPC G01R 33/025; G01R 33/0082

(57) ABSTRACT

A method for processing detection signals of magnetic field sensors, the method comprising generating a magnetic field by an excitation magnet; detecting a magnetic flux density B₁, . . . , Bₙ of the generated magnetic field by means of a number n≥2 of magnetic field sensors S₁, . . . , Sₙ arranged on a circuit main surface of an integrated circuit; outputting detection signals VS1, . . . , VSₙ proportional to the magnetic flux density B₁, . . . , Bn detected by the n magnetic field sensors S1, . . . , Sₙ to the integrated circuit; gain correcting the output detection signals VS1, . . . , VSₙ; transforming the phase-corrected detection signals VS₁′, . . . , VSₙ′ and gain correcting the transformed detection signals Vt₁, Vt₂.

### BACKGROUND OF THE INVENTION

### Field of the Invention

The invention relates to an apparatus and a method for suppressing interference fields in magnetic sensors.

### Brief Description of the Related Art

Apparatuses and methods for determining an angular position of an excitation magnet are known in the prior art. For this purpose, at least one magnetic field sensor is arranged in a magnetic field of an excitation magnet and a detection signal output by the magnetic field sensor is detected.

These magnetic field sensors are often used in regions in which a multiplicity of possible interference variables exist. By way of example, these magnetic field sensors are used in the automobile industry. Particularly in the case of the increasing number of electrical and electronic components in the automobile, however, interference fields also occur to an increased extent, which impede the reliable measurement of the magnetic field and the detection of an angular position of the excitation magnet relative to the magnetic field sensor.

In the prior art, the use of signal processing processors is proposed in order to perform a compensation on the measured values received from the magnetic field sensor and to compensate for the magnetic interference fields. However, this compensation can be realized in a simple manner only for a homogeneous magnetic field. By contrast, the compensation for a magnetic field which is influenced by a multiplicity of interference fields is more extensive since the compensation also has to take account of the field gradient of the generated magnetic field.

### BRIEF SUMMARY OF THE INVENTION

Against this background, the present invention is based on the technical problem of providing a method and an apparatus for reliably detecting an angular position of an excitation magnet.

A method according to a first aspect of the invention for processing signals of magnetic field sensors comprises generating a magnetic field by the excitation magnet, detecting a magnetic flux density of the generated magnetic field by means of a number n≥2 of magnetic field sensors arranged on a circuit main surface of an integrated circuit, outputting detection signals proportional to the magnetic flux density detected by the n magnetic field sensors to the integrated circuit, gain correction of the output detection signals, transforming the gain-corrected detection signals and gain correction of the transformed detection signals. The gain correction of the output detection signals is carried out according to the equation

$${VS}_{i}^{′} = {VS}_{i} * {k}_{g \_ i} , for i = 1 , … , n \\ wherein {k}_{g \_ i} = {A}_{z} / max ( {VS}_{i} ) , for i = 1 , … , n$$

Transforming of the gain-corrected detection signals is carried out according to the equations

$${Vt}_{1} = \sum ( {VS}_{i}^{′} * sin ( \frac{360 °}{n} * ( i - 1 ) + {φ}_{1} ) ) , for i = 1 , … , n \\ and \\ {Vt}_{2} = \sum ( {VS}_{i}^{′} * sin ( \frac{360 °}{n} * ( i - 1 ) + {φ}_{2} ) ) , for i = 1 , … , n , wherein {φ}_{1} \neq {φ}_{2}$$

and wherein preferably φ₂=φ₁+90°.

Gain correction of the transformed detection signals is carried out according to the equations

$${Vt}_{1}^{′} = {Vt}_{1} * {k}_{g \_ out \_ 1} , \\ and \\ {Vt}_{2}^{′} = {Vt}_{2} * {k}_{g \_ out \_ 2} .$$

In the following, it is assumed that all sensor signals have the same amplitude, considered over at least one full period. For the determination of the k_{g_i}, all sensors are stimulated with the same homogeneous magnetic field. k_{g_i} are calculated such that after the gain correction, the sensor signals have the same amplitude when stimulated with the homogeneous magnetic field. One possible way to calculate the k_{g_i} is to select a target amplitude A_{z} which has the optimal value for the subsequent calculations.

Furthermore, it is assumed that the transformed detection signals Vt₁ and Vt₂ have the same amplitude. These two signals are evaluated, for example, in the case of a rotating magnet over at least one full period, in order to determine their amplitudes Avt₁ and Avt₂. Further possibilities for determining the amplitude are known from the prior art. A target amplitude Azt is selected which is optimal for the following calculations. The coefficients are then calculated according to the following equations:

$$Kg\_out \_ 1 = {A}_{zt} / {Avt}_{1} \\ Kg\_out \_ 2 = {A}_{zt} / {Avt}_{2}$$

The method according to the first aspect makes it possible to reliably determine the angular position of an excitation magnet even in the presence of interference fields. A further method according to a second aspect of the invention for processing signals of magnetic field sensors comprises generating a magnetic field by the excitation magnet, detecting a magnetic flux density of the generated magnetic field by means of a number n≥2 of magnetic field sensors arranged on a circuit main surface of an integrated circuit, outputting detection signals proportional to the magnetic flux density detected by the n magnetic field sensors to the integrated circuit, gain correcting of the detection signals, offset correcting of the gain-corrected detection signals, transforming the offset-corrected detection signals, gain correcting of the detection signals and offset correcting of the gain-corrected detection signals.

Gain correcting of the detection signals is carried out according to the equation

$${VS}_{i}^{′} = {VS}_{i} * {k}_{g \_ i} , for i = 1 , … , n \\ wherein {k}_{g \_ i} = {A}_{z} / max ( {VS}_{i} ) , for i = 1 , … , n$$

Offset correcting of the gain-corrected detection signals is carried out according to the equation

$${VS}_{i}^{″} = {VS}_{i}^{′} + {k}_{off \_ i} , for i = 1 , … , n$$

Transforming of the offset-corrected detection signals is carried out according to the equations

$${Vt}_{1} = \sum ( {VS}_{i}^{″} * sin ( \frac{360 °}{n} + ( i - 1 ) + {φ}_{1} ) ) , for i = 1 , … , n \\ and \\ {Vt}_{2} = \sum ( {VS}_{i}^{″} * sin ( \frac{360 °}{n} * ( i - 1 ) + {φ}_{2} ) ) , for i = 1 , … , n , wherein {φ}_{1} \neq {φ}_{2}$$

and wherein preferably φ₂=φ₁+90°.

Gain correcting of the detection signals is carried out according to the equations

$${Vt}_{1}^{′} = {Vt}_{1} * {k}_{g \_ out \_ 1} , \\ and \\ {Vt}_{2}^{′} = {Vt}_{2} * {k}_{g \_ out \_ 2} .$$

Offset correcting of the gain-corrected detection signals is carried out according to the equations

$${Vt}_{1}^{″} = {Vt}_{1}^{′} + {k}_{off \_ out \_ 1} , \\ and \\ {Vt}_{2}^{″} = {Vt}_{2}^{′} + {k}_{off \_ out \_ 2} .$$

The method makes it possible to reliably determine the angular position of an excitation magnet even in the presence of interference fields.

A further method according to a third aspect of the invention for processing signals of magnetic field sensors comprises generating a magnetic field by the excitation magnet, detecting a magnetic flux density of the generated magnetic field by means of a number n=2 of magnetic field sensors arranged on a circuit main surface of an integrated circuit, outputting detection signals proportional to the magnetic flux density detected by the n magnetic field sensors to the integrated circuit and transforming the detection signals. Transforming of the detection signals is carried out according to the equations

$${Vt}_{1} = \sum ( {VS}_{i} * \frac{1}{{r}_{i}} * sin ( {α}_{i} + {φ}_{1} ) ) , for i = 1 , … , n , \\ wherein \sum \frac{1}{{r}_{i}} * sin ( {α}_{i} + {φ}_{1} ) = 0 , for i = 1 , … , n , \\ and \\ {Vt}_{2} = \sum ( {VS}_{i} * \frac{1}{{r}_{i}} * sin ( {α}_{i} + {φ}_{2} ) ) , for i = 1 , … , n , wherein {φ}_{1} \neq {φ}_{2} ,$$

wherein preferably φ₂=φ₁+90° and wherein

$$\sum \frac{1}{{r}_{i}} * sin ( {α}_{i} + {φ}_{1} ) = 0 , for i = 1 , … , n ;$$

wherein αᵢ is the angular position of the respective sensor. For example, when the sensors are arranged equiangularly αᵢ will be (i−1)*(360°/n).

It is noted here that φ₁ and φ₂ are the phase shifts of Vt₁ and Vt₂ relative to a preferred coordinate system when implementing the method shown here. These values are arbitrary, whereby the best results can be achieved with orthogonality φ₂=φ₁+90°.

The method makes it possible to reliably determine the angular position of an excitation magnet even in the presence of interference fields.

A further method according to a fourth aspect of the invention for processing signals of magnetic field sensors comprises generating a magnetic field by the excitation magnet, detecting a magnetic flux density of the generated magnetic field by means of a number n=2 of magnetic field sensors arranged on a circuit main surface of an integrated circuit, outputting detection signals proportional to the magnetic flux density detected by the n magnetic field sensors to the integrated circuit, carrying out a first phase correction of the output detection signals, gain correcting of the phase-corrected detection signals, offset correcting of the gain-corrected detection signals, transforming the offset-corrected detection signals, performing a second phase correction of the transformed detection signals, gain correcting of the phase-corrected detection signals and offset correcting of the gain-corrected detection signals. Performing the first phase correction of the output detection signals is carried out according to the equation

$${VS}_{i}^{′} = {VS}_{i} + {k}_{ph \_ i} * {VS}_{j} , for \\ i = 1 , … , n , for j = 1 , … , n and wherein j \neq i .$$

Gain correcting of the phase-corrected detection signals is carried out according to the equation

$${VS}_{i}^{″} = {VS}_{i}^{′} * {k}_{g \_ i} , for i = 1 , … , n$$

Offset correcting of the gain-corrected detection signals is carried out according to the equation

$${VS}_{i}^{′′′} = {VS}_{i}^{″} + {k}_{off \_ i} , for i = 1 , … , n$$

Transforming of the offset-corrected detection signals is carried out according to the equations

$${Vt}_{1} = \sum ( {VS}_{i}^{′′′} * sin ( \frac{360 °}{n} * ( i - 1 ) + {φ}_{1} ) ) , for i = 1 , … , n and$$

$${Vt}_{2} = \sum ( {VS}_{i}^{′′′} * sin ( \frac{360 °}{n} * ( i - 1 ) + {φ}_{2} ) ) , for i = 1 , … , n ,$$

$$wherein {φ}_{1} \neq {φ}_{2}$$

and wherein preferably φ₂=φ₁+90°.

Performing the second phase correction of the transformed detection signals is carried out according to the equations

$${Vt}_{1}^{′} = {Vt}_{1} + {k}_{ph \_ out \_ 1} * {Vt}_{2} , and$$

$${Vt}_{2}^{′} = {Vt}_{2} + {k}_{ph \_ out \_ 2} * {Vt}_{1} .$$

Gain correcting of the phase-corrected detection signals is carried out according to the equations

$${Vt}_{1}^{″} = {Vt}_{1}^{′} * {k}_{g \_ out \_ 1} , and$$

$${Vt}_{2}^{″} = {Vt}_{2}^{′} * {k}_{g \_ out \_ 2} .$$

Offset correcting of the gain-corrected detection signals is carried out according to the equations

$${Vt}_{1}^{′′′} = {Vt}_{1}^{″} + {k}_{off \_ out \_ 1} , and$$

$${Vt}_{2}^{′′′} = {Vt}_{2}^{″} + {k}_{off \_ out \_ 2} .$$

The method makes it possible to reliably determine the angular position of an excitation magnet even in the presence of interference fields.

The above methods according to any one of the first to fourth aspects can advantageously be used for stray field suppression. Hence the impact of stray field possible acting on the magnetic field sensors S₁, . . . , Sₙ. can be reduced to obtain improved results.

An apparatus according to a fifth, sixth, seventh and eighth aspect of the present invention is for detecting an angular position of an excitation magnet using one of the abovementioned methods according to any one of the first to fourth aspects, respectively and comprises an integrated circuit and a number n=2 of magnetic field sensors. The integrated circuit has a circuit main surface which is arranged orthogonally with respect to an axis of rotation of the excitation magnet. The number n≥2 of magnetic field sensors are arranged on the circuit main surface and configured to output detection signals which are proportional to a flux density of the excitation magnet detected by the magnetic field sensors. More precisely, each magnetic field sensor outputs a respective detection signal which is proportional to the magnetic flux density of the excitation magnet detected by that magnetic field sensor.

With any of the above apparatus, it is possible to reliably detect the angular position of the excitation magnet.

In an apparatus according to a ninth aspect of the present invention, according to any one of the fifth, sixth or eighth aspects the n magnetic field sensors are arranged on the circuit main surface at a distance from the axis of rotation by a radius. Hence, in order to allow for a more variable and/or more reliable setup the sensors can for example be all arranged on one single and same radius, or they can be distributed on a plurality of radii from the axis of rotation i.e. lie on different concentric circles with a radius relative to the axis of rotation. In other words, according to preferred aspects Ri is the same for all, or for some of the sensors, respectively.

With this apparatus, it is possible to reliably detect the angular position of the excitation magnet.

In an apparatus according to a ninth aspect of the present invention, according to any one of the fifth, sixth, eighth and ninth aspects the n magnetic field sensors are arranged on the circuit main surface equiangularly about the axis of rotation. Hence, the packaging of the magnetic field sensors can be achieved to be simpler and more cost effective.

With this apparatus, it is possible to reliably detect the angular position of the excitation magnet.

The above apparatus according to any one of the fifth to nineth aspects can advantageously be used for stray field suppression. Hence, the impact of stray fields possibly acting on magnetic field sensors S₁, . . . , Sₙ can be reduced.

### BRIEF DESCRIPTION OF THE FIGURES

For a more complete understanding of the present invention and the advantages thereof, reference is now made to the following description and the accompanying drawings, in which:

FIG. 1 is a plan view of an apparatus for detecting an angular position of an excitation magnet.

FIG. 2 is a side view of the apparatus for detecting the angular position of the excitation magnet.

FIG. 3 shows a process flow diagram which describes a method for processing detection signals of magnetic field sensors.

FIG. 4 shows a process flow diagram which describes a further method for processing detection signals of magnetic field sensors.

FIG. 5 shows a process flow diagram which describes a further method for processing detection signals of magnetic field sensors.

FIG. 6 shows a process flow diagram which describes a further method for processing detection signals of magnetic field sensors.

### DETAILED DESCRIPTION OF THE INVENTION

The invention will now be described on the basis of the drawings. It is assumed that the embodiments and aspects of the invention described here are only examples and in no way intended to limit the scope of protection of the claims. The invention is defined by the claims and their equivalents. It is assumed that features of one aspect or one embodiment of the invention can be combined with a feature of another aspect or other aspects and/or embodiments of the invention.

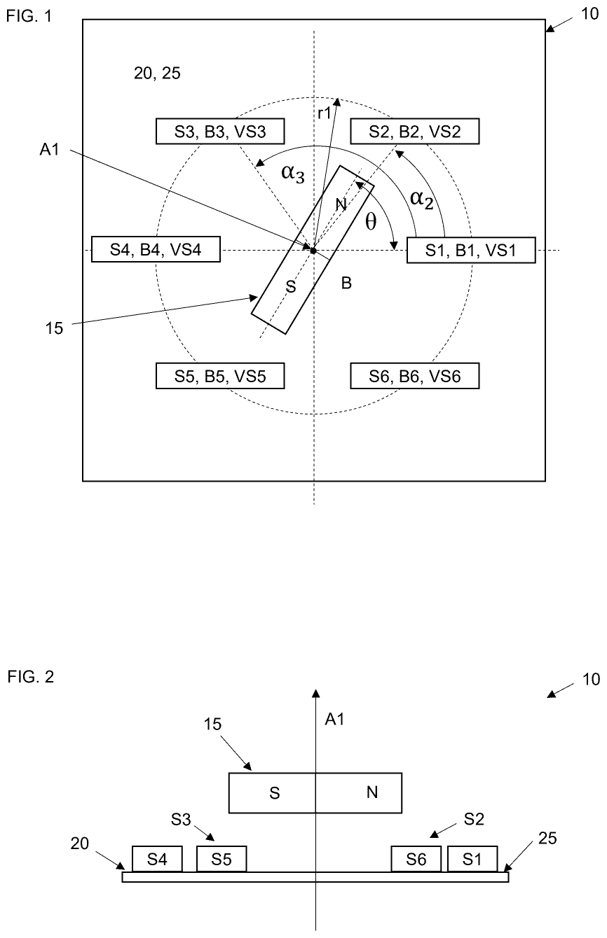

FIG. 1 shows an apparatus 10 for detecting an angular position θ of an excitation magnet 15. The apparatus 10 comprises an integrated circuit 20 and a number n=2 of magnetic field sensors S₁, . . . , Sₙ. The integrated circuit 20 has a circuit main surface 25 which is arranged orthogonally with respect to an axis of rotation A1 of the excitation magnet 15.

The number n of magnetic field sensors S₁, . . . , Sₙ are arranged at arbitrary locations on the circuit main surface 25 and configured to output a detection signal VS₁, . . . , VSₙ which is proportional to a magnetic flux density B₁, . . . , Bₙ of the excitation magnet 15 detected by the n magnetic field sensors S₁, . . . , Sₙ.

The n magnetic field sensors S₁, . . . , Sₙ are preferably arranged on the circuit main surface 25 at a distance from the axis of rotation A1 by a radius r. However, the n magnetic field sensors S₁, . . . , Sₙ may also be at a distance from the axis of rotation A1 by different radii r₁, . . . , rₙ, i.e. lie on different concentric circles with a radius r₁, . . . , rₙ relative to the axis of rotation A1 (for the purpose of simplifying the illustration, only the radius r₁ is shown in FIG. 1).

Furthermore, the n magnetic field sensors S₁, . . . , Sₙ are preferably arranged on the circuit main surface 25 equiangularly about the axis of rotation A1. However, the n magnetic field sensors S₁ . . . , Sₙ may also be arranged at different angular positions α₁, . . . , αₙ with respect to the axis of rotation A1 (for the purpose of simplifying the illustration, the second angular position α₂ of the second magnetic field sensor S₂ and the third angular position α₃ of the third magnetic field sensor S₃ are illustrated only by way of example in FIG. 1).

FIG. 2 shows a side view of the apparatus 10 for detecting the angular position θ of the excitation magnet 15. The number n of magnetic field sensors S₁, . . . , Sₙ are arranged on the circuit main surface 25 in order to detect the angular position θ of the excitation magnet 15. In the configuration illustrated in FIG. 1 and FIG. 2, a number n=6 magnetic field sensors S₁, . . . , Sₙ (denoted by S₁ to S₆ in FIG. 1 for the purpose of simplification) are arranged on the circuit main surface 25.

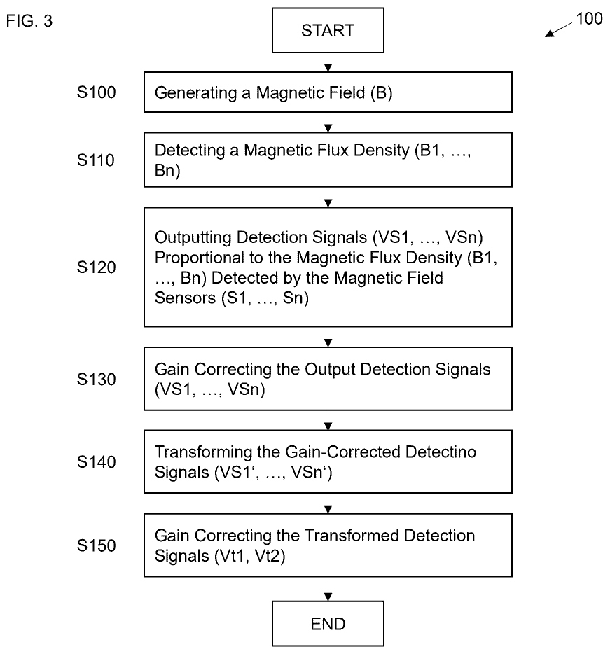

FIG. 3 is a process flow diagram of a method 100 for processing detection signals of magnetic field sensors allowing for detecting the angular position θ of the excitation magnet 15. In step S100, the method 100 comprises generating the magnetic field B by the excitation magnet 15.

The method 100 furthermore comprises, in step S110, detecting a magnetic flux density B₁, . . . , Bₙ of the generated magnetic field B by means of the number n=2 of magnetic field sensors S₁, . . . , Sₙ arranged on the circuit main surface 25 of the integrated circuit 20.

The method 100 furthermore comprises, in step S120, outputting detection signals VS₁, . . . , VSₙ proportional to the magnetic flux density B₁, . . . , Bₙ detected by the n magnetic field sensors S₁, . . . , Sₙ to the integrated circuit 20.

The method 100 furthermore comprises, in step S130, gain correcting the output detection signals VS₁, . . . , VSₙ according to the following equation, in which k_{g_i} denotes a correction factor for gain correction

$${VS}_{i}^{′} = {VS}_{i} * {k}_{g \_ i} for i = 1 , … , n \qquad ( 1 )$$

The method 100 furthermore comprises, in step S140, transforming the gain-corrected detection signals VS₁′, . . . , VSₙ′ according to the equations

$${Vt}_{1} = \sum ( {VS}_{i}^{′} * sin ( \frac{360 °}{n} * ( i - 1 ) + {φ}_{1} ) ) , for i = 1 , … , n$$

$${Vt}_{2} = \sum ( {VS}_{i}^{′} * sin ( \frac{360 °}{n} * ( i - 1 ) + {φ}_{2} ) ) , for i = 1 , … , n ,$$

$$wherein {φ}_{1} \neq {φ}_{2}$$

and wherein preferably φ₂=φ₁+90°

The method 100 furthermore comprises, in step S150, gain correcting the transformed detection signals Vt₁, Vt₂ according to the following equations, in which k_{g_out_1} and k_{g_out_2} denote correction factors for gain correction

$${Vt}_{1}^{′} = {Vt}_{1} * {k}_{g \_ out \_ 1}$$

$${Vt}_{2}^{′} = {Vt}_{2} * {k}_{g \_ out \_ 2}$$

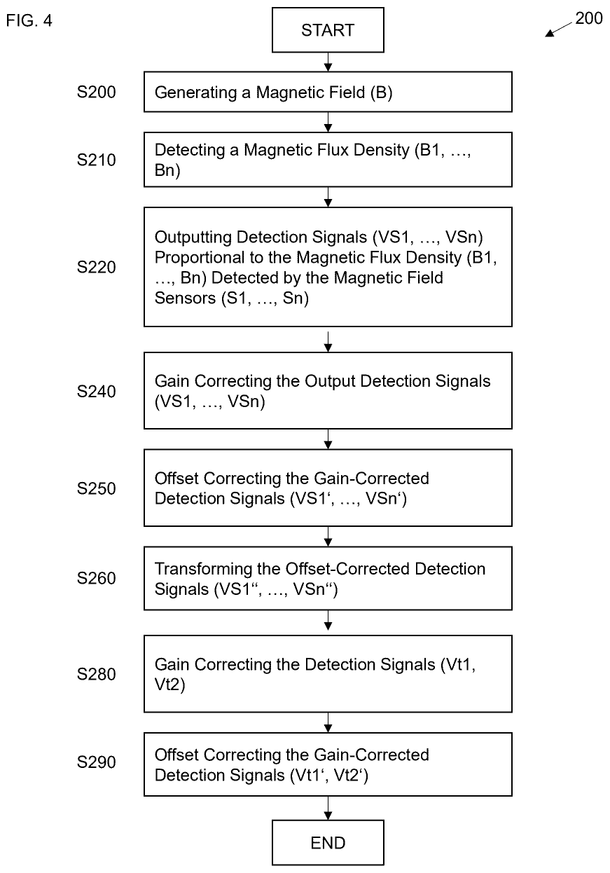

FIG. 4 is a process flow diagram of a method 200 for processing detection signals of magnetic field sensors allowing for detecting the angular position θ of the excitation magnet 15. In step S200, the method 200 comprises generating the magnetic field B by the excitation magnet 15.

The method 200 furthermore comprises, in step S210, detecting the magnetic flux density B₁, . . . , Bₙ of the generated magnetic field B by means of the number n=2 of magnetic field sensors S₁, . . . , Sₙ arranged on the circuit main surface 25 of the integrated circuit 20.

The method 200 furthermore comprises, in step S220, outputting detection signals VS₁, . . . , VSₙ proportional to the magnetic flux density B₁, . . . , Bₙ detected by the n magnetic field sensors S₁, . . . , Sₙ to the integrated circuit 20.

The method 200 furthermore comprises, in step S240, gain correcting the detection signals VS₁, . . . , VSₙ according to the following equation, in which k_{g_i} denotes a correction factor for gain correction.

$${VS}_{i}^{′} = {VS}_{i} * {k}_{g \_ i} , for i = 1 , … , n \qquad ( 2 )$$

The method 200 furthermore comprises, in step S250, offset correcting the gain-corrected detection signals VSᵢ′, . . . , VSₙ′ according to the equation

$${VS}_{i}^{″} = {VS}_{i}^{′} + {k}_{off \_ i} , . for i = 1 , … , n \qquad ( 3 )$$

The method 200 furthermore comprises, in step S260, transforming the offset-corrected detection signals VSᵢ″, . . . , VSₙ″ according to the equation

$${Vt}_{1} = \sum ( {VS}_{i}^{″} * sin ( \frac{360 °}{n} * ( i - 1 ) + {φ}_{1} ) ) , for i = 1 , … , n$$

$${Vt}_{2} = \sum ( {VS}_{i}^{″} * sin ( \frac{360 °}{n} * ( i - 1 ) + {φ}_{2} ) ) , for i = 1 , … , n ,$$

$$wherein {φ}_{1} \neq {φ}_{2}$$

and wherein preferably φ₂=φ₁+90°

The method 200 furthermore comprises, in step S280, gain correcting S280 the detection signals Vt₁, Vt₂ according to the following equations, in which k_{g_out_1} and k_{g_out_2} denote correction factors for gain correction.

$${Vt}_{1}^{′} = {Vt}_{1} * {k}_{g \_ out \_ 1}$$

$${Vt}_{2}^{′} = {Vt}_{2} * {k}_{g \_ out \_ 2}$$

The method 200 furthermore comprises, in step S290, offset correcting the gain-corrected detection signals Vt₁′, Vt₂′ according to the following equations, in which k_{off_out_1} and k_{off_out_2} denote correction factors for offset correction.

$${Vt}_{1}^{″} = {Vt}_{1}^{′} + {k}_{off \_ out \_ 1}$$

$${Vt}_{2}^{″} = {Vt}_{2}^{′} + {k}_{off \_ out \_ 2}$$

It will be apparent to the person skilled in the art that steps S230, S240, S250 can be interchanged without deviating from the subject matter of the invention. In addition, it will be apparent to the person skilled in the art that steps S270, S280, S290 can be interchanged without deviating from the subject matter of the invention.

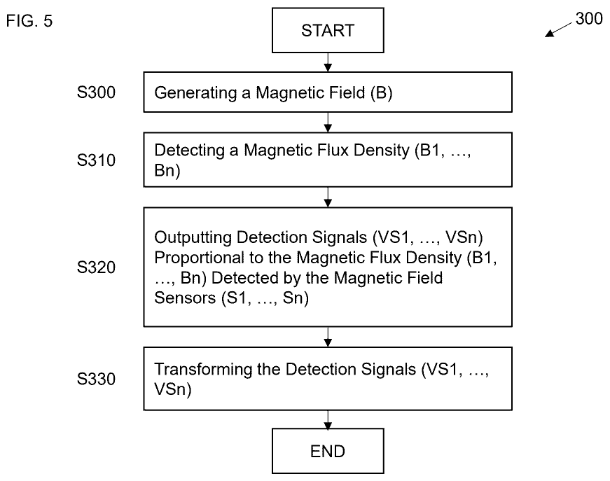

FIG. 5 is a process flow diagram of a method 300 for processing detection signals of magnetic field sensors allowing for detecting the angular position θ of the excitation magnet 15 by means of magnetic field sensors S₁, . . . , Sₙ arranged arbitrarily on the circuit main surface 25. The magnetic field sensors S₁, . . . , Sₙ may in this case be arranged on the circuit main surface 25 at arbitrary distances from one another and at a different distance from the axis of rotation A1 of the excitation magnet 15. However, the magnetic field sensors S₁, . . . , Sₙ are preferably distributed equiangularly about the axis of rotation A1.

In step S300, the method 300 comprises generating the magnetic field B by the excitation magnet 15.

The method 300 furthermore comprises, in step S310, detecting the magnetic flux density B₁, . . . , Bₙ of the generated magnetic field B by means of the number n≥2 of magnetic field sensors S₁, . . . , Sₙ arranged on the circuit main surface 25 of the integrated circuit 20.

The method 300 furthermore comprises, in step S320, outputting the detection signal VS₁, . . . , VSₙ proportional to the magnetic flux density B₁, . . . , Bₙ detected by the n magnetic field sensors S₁, . . . , Sₙ to the integrated circuit 20.

The method 300 furthermore comprises, in step S330, transforming S330 the detection signals VS₁, . . . , VSₙ according to the equation

$$V {t}_{1} = \sum ( {VS}_{i} ⋆ \frac{1}{{r}_{i}} ⋆ sin ( {α}_{i} + {φ}_{1} ) ) , f \ddot{u} r i = 1 , … , n wherein \sum \frac{1}{{r}_{i}} ⋆ sin ( {α}_{i} + {φ}_{1} ) = 0 , for i = 1 , … , n$$

$$V {t}_{2} = \sum ( {VS}_{i} * \frac{1}{{r}_{i}} * sin ( {α}_{i} + {φ}_{2} ) ) , f \ddot{u} r i = 1 , … , n , wherein {φ}_{1} \neq {φ}_{2 ,}$$

wherein preferably φ₂=φ₁+90° and wherein

$$\sum \frac{1}{{r}_{i}} * sin ( {α}_{i} + {φ}_{1} ) = 0 , for i = 1 , … , n$$

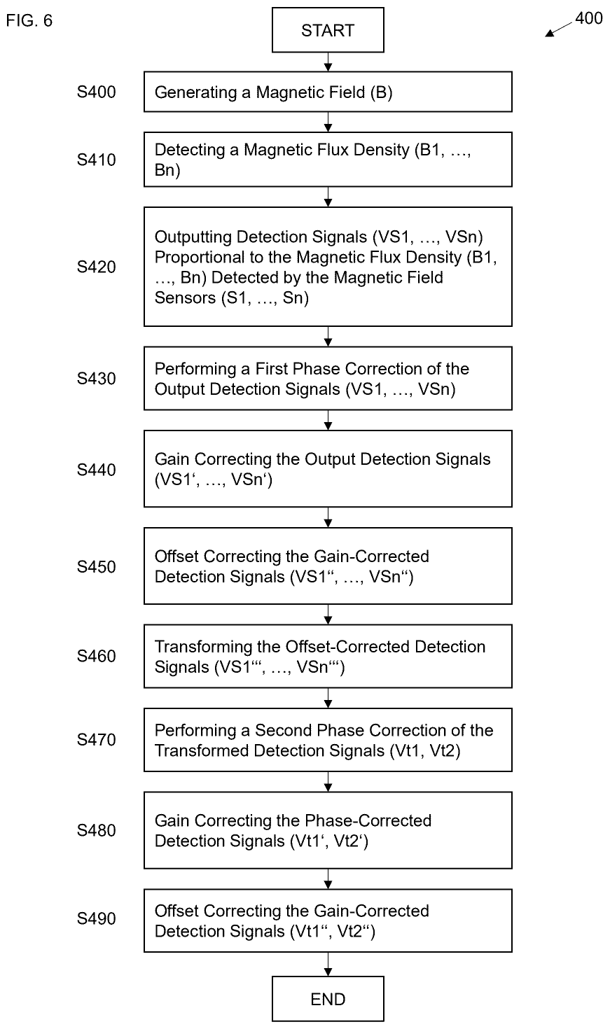

FIG. 6 is a process flow diagram of a method 400 for processing detection signals of magnetic field sensors allowing for detecting the angular position θ of the excitation magnet 15. In step S400, the method 400 comprises generating the magnetic field B by the excitation magnet 15.

The method 400 furthermore comprises, in step S410, detecting the magnetic flux density B₁, . . . , Bₙ of the generated magnetic field B by means of the number n=2 of magnetic field sensors S₁, . . . , Sₙ arranged on the circuit main surface 25 of the integrated circuit 20.

The method 400 furthermore comprises, in step S420, outputting detection signals VS₁, . . . , VSₙ proportional to the magnetic flux density B₁, . . . , Bₙ detected by the n magnetic field sensors S₁, . . . , Sₙ to the integrated circuit 20.

The method 400 furthermore comprises, in step S430, performing a first phase correction of the output detection signals VS₁, . . . , VSₙ according to the following equation, in which k_{ph_i} denotes a correction factor for phase correction.

$${VS}_{i}^{′} = {VS}_{i} + {k}_{ph \_ i} * {VS}_{j} , for \\ i = 1 , … , n , for j = 1 , … , n and wherein j \neq i$$

The method 400 furthermore comprises, in step S440, gain correcting the phase-corrected detection signals VSᵢ′, . . . , VSₙ′ according to the following equation, in which k_{g_i} denotes a correction factor for gain correction.

$${VS}_{i}^{′′} = {VS}_{i}^{′} * {k}_{g \_ i} , for i = 1 , … , n \qquad ( 4 )$$

The method 200 furthermore comprises, in step S450, offset correcting the gain-corrected detection signals VSᵢ″, . . . , VSₙ″ according to the equation

$${VS}_{i}^{′′′} = {VS}_{i}^{′′} + {k}_{{off \_ i}^{′}} , for i = 1 , … , n \qquad ( 5 )$$

The method 400 furthermore comprises, in step S460, transforming the offset-corrected detection signals VSᵢ′″, . . . , VSₙ′″ according to the equation

$${Vt}_{1} = \sum ( {VS}_{i}^{′′′} * sin ( \frac{36 {0}^{∘}}{n} * ( i - 1 ) + {φ}_{1} ) ) , for i = 1 , … , n$$

$$V {t}_{2} = \sum ( {VS}_{i}^{′′′} * sin ( \frac{36 {0}^{∘}}{n} * ( i - 1 ) + {φ}_{2} ) ) , for i = 1 , … , n , wherein {φ}_{1}$$

$$\neq {φ}_{2}$$

and wherein preferably φ₂=φ₁+90°

The method 400 furthermore comprises, in step S470, performing a second phase correction of the transformed detection signals Vt₁, Vt₂ according to the following equations, in which k_{ph_out_1} and k_{ph_out_2} denote correction factors for phase correction.

$$\begin{matrix}{Vt}_{1}^{′} = {Vt}_{1} + {k}_{ph \_ out \_ 1} * V {t}_{2} \\ {Vt}_{2}^{′} = {Vt}_{2} + {k}_{ph \_ out \_ 2} * V {t}_{1}\end{matrix}$$

The method 400 furthermore comprises, in step S480, gain correcting S480 the phase-corrected detection signals vt₁′, vt₂′ according to the following equations, in which k_{g_out_1} and k_{g_out_2} denote correction factors for gain correction.

$$\begin{matrix}{Vt}_{1}^{′′} = {Vt}_{1}^{′} * {k}_{g \_ out \_ 1} \\ {Vt}_{2}^{′′} = {Vt}_{2}^{′} * {k}_{g \_ out \_ 2}\end{matrix}$$

The method 400 furthermore comprises, in step S490, offset correcting the gain-corrected detection signals vt₁″, vt₂″ according to the following equations, in which k_{off_out_1} and k_{off_out_2} denote correction factors for offset correction.

$$\begin{matrix}{Vt}_{1}^{′′′} = {Vt}_{1}^{′′} + {k}_{off \_ out \_ 1} \\ {Vt}_{2}^{′′′} = {Vt}_{2}^{′′} + {k}_{off \_ out \_ 2}\end{matrix}$$

It will be apparent to the person skilled in the art that steps S430, S440, S450 can be interchanged without deviating from the subject matter of the invention. In addition, it will be apparent to the person skilled in the art that steps S470, S480, S490 can be interchanged without deviating from the subject matter of the invention. The abovementioned formulae (6), (7) and (8) are adapted in such a case by reference to an upstream step; this likewise applies to formulae (11) to (16).

### REFERENCE SIGNS LIST

10 Apparatus
15 Excitation magnet
20 Integrated circuit
25 Circuit main surface
A1 Axis of rotation
r₁ . . . , rₙ Radius
S₁ . . . , Sₙ Magnetic field sensors
α₁, . . . , αₙ Angular positions of the magnetic field sensors
θ Angular position of the excitation magnet
VS₁ . . . , VSₙ Detection signal
B magnetic field
B₁, . . . , Bₙ detected magnetic flux density

What is claimed is:

1. A method for processing detection signals of magnetic field sensors, the method comprising:
generating a magnetic field (B) by the excitation magnet;
detecting a magnetic flux density B₁, . . . , Bₙ of the generated magnetic field by means of a number n≥2 of magnetic field sensors S₁, . . . , Sₙ arranged on a circuit main surface of an integrated circuit (20);
outputting (S120) detection signals VS₁, . . . , VSₙ proportional to the magnetic flux density (B₁, . . . , Bₙ) detected by the n magnetic field sensors S1, . . . , Sₙ to the integrated circuit;
gain correcting the output detection signals VS₁, . . . , VSₙ according to the equation
$$V {S}_{i}^{′} = V {S}_{i} * {k}_{g \_ i} , for i = 1 , … , n$$
transforming the gain-corrected detection signals VS₁′, . . . , VSₙ′ according to the equations
$${Vt}_{1} = \sum ( V {S}_{i}^{′} * sin ( \frac{36 {0}^{∘}}{n} * ( i - 1 ) + {φ}_{1} ) ) , for i = 1 , … , n$$
$$and$$
$$V {t}_{2} = \sum ( V {S}_{i}^{′} * sin ( \frac{36 {0}^{∘}}{n -} * ( i - 1 ) + {φ}_{2} ) ) , for i = 1 , … , n , wherein {φ}_{1}$$
$$\neq {φ}_{2}$$
and wherein preferably φ₂=φ₁+90°
gain correcting (S150) the transformed detection signals (Vt₁, Vt₂) according to the equations
$$V {t}_{1}^{′} = V {t}_{1} * {k}_{g \_ out \_ 1}$$
$$and$$
$$V {t}_{2}^{′} = V {t}_{2} * {k}_{g \_ out \_ 2} .$$

2. Use of the method according to claim 1 for stray field suppression.

3. An apparatus for detecting an angular position of an excitation magnet using the method according to claim 1, the apparatus comprising:
an integrated circuit having a circuit main surface, wherein the circuit main surface is arranged orthogonally to an axis of rotation of the excitation magnet; and
a number n≥2 of magnetic field sensors S₁, . . . , Sₙ, wherein the n magnetic field sensors S₁, . . . , Sₙ are arranged on the circuit main surface, and wherein the n magnetic field sensors S₁, . . . , Sₙ are configured to output detection signals VS₁, . . . , VSₙ which are proportional to a magnetic flux density B₁, . . . , Bₙ of the excitation magnet detected by the n magnetic field sensors S1, . . . , Sₙ.

4. The apparatus according to claim 3, in which
the n magnetic field sensors are arranged on the circuit main surface spaced apart from the axis of rotation by a radius.

5. The apparatus according to claim 4, in which
the n magnetic field sensors S₁, . . . , Sₙ are arranged on the circuit main surface equiangularly about the axis of rotation.

6. Use of the apparatus according to claim 3 for stray field suppression.

7. A method for processing detection signals of magnetic field sensors, the method comprising:
generating a magnetic field by the excitation magnet;
detecting a magnetic flux density B₁, . . . , Bₙ of the generated magnetic field by means of a number n≥2 of magnetic field sensors S₁, . . . , Sₙ arranged on a circuit main surface of an integrated circuit;
outputting detection signals VS₁, . . . , VSₙ proportional to the magnetic flux density detected by the n magnetic field sensors S₁, . . . , Sₙ, to the integrated circuit;
gain correcting the detection signals VS₁, . . . , VSₙ according to the equation
$$V {S}_{i}^{′} = V {S}_{i} * {k}_{g \_ i} , for i = 1 , … , n$$
offset correcting the gain-corrected detection signals VS₁′, . . . , VSₙ′ according to the equation
$$\begin{matrix}{VS}_{i}^{′′} = {VS}_{i}^{′} + {k}_{off\_i} , & for i = 1 , … , n\end{matrix}$$
transforming the offset-corrected detection signals VS₁″, . . . , VSₙ″ according to the equations
$${Vt}_{1} = \sum ( {VS}_{i}^{′′} * sin ( \frac{36 {0}^{∘}}{n} * ( i - 1 ) + {φ}_{1} ) ) , for i = 1 , … , n$$
$$V {t}_{2} = \sum ( V {S}_{i}^{′′} * sin ( \frac{36 {0}^{∘}}{n -} * ( i - 1 ) + {φ}_{2} ) ) , for i = 1 , … , n , wherein {φ}_{1}$$
$$\neq {φ}_{2}$$
and wherein preferably φ₂=φ₁+90°
gain correcting the detection signals (vt₁, vt₂) according to the equations
$$V {t}_{1}^{′} = V {t}_{1} * {k}_{g \_ out \_ 1}$$
$$V {t}_{2}^{′} = V {t}_{2} * {k}_{g \_ out \_ 2}$$
offset correcting the gain-corrected detection signals (vt₁′, vt₂′) according to the equations
$${Vt}_{1}^{″} = {Vt}_{1}^{′} + {k}_{off \_ out \_ 1} \\ {Vt}_{2}^{″} = {Vt}_{2}^{′} + {k}_{off \_ out \_ 2} .$$

8. Use of the method according to claim 7 for stray field suppression.

9. An apparatus for processing detection signals of magnetic field sensors using the method according to claim 7, the apparatus comprising:
an integrated circuit having a circuit main surface, wherein the circuit main surface is arranged orthogonally to an axis of rotation of the excitation magnet; and
a number n≥2 of magnetic field sensors S₁, . . . , Sₙ, wherein the n magnetic field sensors S₁, . . . , Sₙ are arranged on the circuit main surface, and wherein the n magnetic field sensors S₁, . . . , Sₙ are configured to output detection signals VS₁, . . . , VSₙ which are proportional to a magnetic flux density B₁, . . . , Bₙ of the excitation magnet detected by the n magnetic field sensors S₁, . . . , Sₙ.

10. The apparatus according to claim 9, in which
the n magnetic field sensors are arranged on the circuit main surface spaced apart from the axis of rotation by a radius.

11. The apparatus according to claim 10, in which
the n magnetic field sensors S₁, . . . , Sₙ are arranged on the circuit main surface equiangularly about the axis of rotation.

12. Use of the apparatus according to claim 9 for stray field suppression.

13. A method for processing detection signals of magnetic field sensors, the method comprising:
generating a magnetic field by the excitation magnet;
detecting a magnetic flux density B₁, . . . , Bₙ of the generated magnetic field by means of a number n≥2 of magnetic field sensors S₁, . . . , Sₙ arranged on a circuit main surface of an integrated circuit;
outputting detection signals VS₁, . . . , VSₙ proportional to the magnetic flux density B₁, . . . , Bₙ detected by the n magnetic field sensors S1, . . . , Sₙ to the integrated circuit; and
transforming (S₃₃₀) the detection signals VS₁, . . . , VSₙ according to the equations
$${Vt}_{1} = \sum ( {VS}_{i} * \frac{1}{{r}_{i}} * sin ( {α}_{i} + {φ}_{1} ) ) , for \\ i = 1 , … , n wherein \sum \frac{1}{{r}_{i}} * sin ( {α}_{i} + {φ}_{1} ) = 0 , for i = 1 , … , n \\ {Vt}_{2} = \sum ( {VS}_{i} * \frac{1}{{r}_{i}} * sin ( {α}_{i} + {φ}_{2} ) ) , for i = 1 , … , n , wherein {φ}_{1} \neq {φ}_{2} ,$$
wherein preferably φ₂=φ₁+90° and wherein
$$\sum \frac{1}{{r}_{i}} * sin ( {α}_{i} + {φ}_{1} ) = 0 , für i = 1 , … , n .$$

14. Use of the method according to claim 13 for stray field suppression.

15. An apparatus for processing detection signals of magnetic field sensors using the method according to claim 13, the apparatus comprising:
an integrated circuit having a circuit main surface, wherein the circuit main surface is arranged orthogonally to an axis of rotation of the excitation magnet; and
a number n≥2 of magnetic field sensors S₁, . . . , Sₙ, wherein the n magnetic field sensors S₁, . . . , Sₙ are arranged on the circuit main surface, and wherein the n magnetic field sensors S₁, . . . , Sₙ are configured to output detection signals VS₁, . . . , VSₙ which are proportional to a magnetic flux density B₁, . . . , Bₙ of the excitation magnet detected by the n magnetic field sensors S₁, . . . , Sₙ.

16. Use of the apparatus according to claim 15 for stray field suppression.

17. A method for processing detection signals of magnetic field sensors, the method comprising:
generating a magnetic field by the excitation magnet;
detecting a magnetic flux density B₁, . . . , Bₙ of the generated magnetic field by means of a number n≥2 of magnetic field sensors S₁, . . . , Sₙ arranged on a circuit main surface of an integrated circuit;
outputting detection signals VS₁, . . . , VSₙ proportional to the magnetic flux density B₁, . . . , Bₙ detected by the n magnetic field sensors S₁, . . . , Sₙ to the integrated circuit;
performing a first phase correction of the output detection signals VS₁, . . . , VSₙ according to the equation
$${VS}_{i}^{′} = {VS}_{i} + {k}_{ph \_ i} * {VS}_{j} , for \\ i = 1 , … , n , for j = 1 , … , n and wherein j \neq i$$
gain correcting of the phase-corrected detection signals VS₁′, . . . , VSₙ′ according to the equation
$${VS}_{i}^{″} = {VS}_{i}^{′} * {k}_{{g}_{\_ i}} , for i = 1 , … , n$$
offset correcting of the gain-corrected detection signals VS₁′″, . . . , VSₙ′″ according to the equation
$${VS}_{i}^{′′′} = {VS}_{i}^{″} + {k}_{off \_ i} , for i = 1 , … , n$$
transforming the offset-corrected detection signals VS₁″′, . . . , VSₙ″′ according to the equations
$${Vt}_{1} = \sum ( {VS}_{i}^{′′′} * sin ( \frac{360 °}{n} * ( i - 1 ) + {φ}_{1} ) ) , for i = 1 , … , n \\ {Vt}_{2} = \sum ( {VS}_{i}^{′′′} sin ( \frac{360 °}{n} * ( i - 1 ) + {φ}_{2} ) ) , for i = 1 , … , n , wherin {φ}_{1} \neq {φ}_{2}$$
and wherein preferably φ₂=φ₁+90°
performing a second phase correction of the transformed detection signals (Vt₁, Vt₂) according to the equations
$${Vt}_{1}^{′} = {Vt}_{1} + {k}_{ph \_ out \_ 1} * {Vt}_{2} \\ {Vt}_{2}^{′} = {Vt}_{2} + {k}_{ph \_ out \_ 2} * {Vt}_{1}$$
gain correcting of the phase-corrected detection signals (vt₁′, vt₂′) according to the
$${Vt}_{1}^{″} = {Vt}_{1}^{′} * {k}_{g \_ out \_ 1} \\ {Vt}_{2}^{″} = {Vt}_{2}^{′} * {k}_{g \_ out \_ 2}$$
offset correcting of the gain-corrected detection signals (vt₁″, vt₂″) according to the equations
$${Vt}_{1}^{′′′} = {Vt}_{1}^{″} + {k}_{off \_ out \_ 1} \\ {Vt}_{2}^{′′′} = {Vt}_{2}^{″} + {k}_{off \_ out \_ 2} .$$

18. Use of the method according to claim 17 for stray field suppression.

19. An apparatus for processing detection signals of magnetic field sensors using the method according to claim 17, the apparatus comprising:
an integrated circuit having a circuit main surface, wherein the circuit main surface is arranged orthogonally to an axis of rotation of the excitation magnet; and
a number n≥2 of magnetic field sensors S₁, . . . , Sₙ, wherein the n magnetic field sensors S₁, . . . , Sₙ are arranged on the circuit main surface, and wherein the n magnetic field sensors S₁, . . . , Sₙ are configured to output detection signals VS₁, . . . , VSₙ which are proportional to a magnetic flux density B₁, . . . , Bₙ of the excitation magnet detected by the n magnetic field sensors S1, . . . , Sₙ.

20. The apparatus according to claim 19, in which
the n magnetic field sensors are arranged on the circuit main surface spaced apart from the axis of rotation by a radius.

21. The apparatus according to claim 20, in which
the n magnetic field sensors S₁, . . . , Sₙ are arranged on the circuit main surface equiangularly about the axis of rotation.

22. Use of the apparatus according to claim 19 for stray field suppression.
